(19) United States
(12) Patent Application Publication
(10) Pub. No.: US 2013/0000691 A1
(43) Pub. Date: Jan. 3, 2013

(54) APPARATUS FOR CONCENTRATING SOLAR ENERGY

(76) Inventor: Oren Aharon, Haifa (IL)

(21) Appl. No.: 12/305,369

(22) PCT Filed: Jun. 18, 2007
(86) PCT No.: PCT/IL07/00734

§ 371 Date: May 12, 2011

(30) Foreign Application Priority Data
Jun. 19, 2006 (IL) 176390

(51) Int. Cl. H01L 31/052

(52) U.S. Cl. 136/246

(57) ABSTRACT

A solar radiation concentrating apparatus including one or more solar energy cells for converting radiation to another form of energy; two planar mirror elements, oriented to reflect solar radiation and to concentrate the radiation onto the solar energy cell. The mirror elements are oriented substantially orthogonally to each other and to the solar cell. The two planar mirror elements and solar energy cell are arranged in a configuration of three mutually perpendicular joined surfaces.

### TECHNICAL FIELD OF THE INVENTION

The present invention relates to solar energy, in particular to a relatively low cost solar energy apparatus. Specifically, the invention relates to an arrangement of mirrors and solar cells preferably oriented to each other similar to an optical retroreflector layout.

### BACKGROUND OF THE INVENTION

Solar energy plays an important role in variety of applications such as energy for remote locations, agriculture, utility grid support, telecommunication, industrial processes, and other green environmental energy resources. Photovoltaic devices are used in the leading technology to is convert solar energy into electricity. Technologically, a photovoltaic power system is capable of providing energy for any purpose, the main drawback being cost and efficiency.

As the price of fuel has increased dramatically and the adverse effect of fossil energy is now clear, the market for solar energy systems has increased dramatically. In addition, other characteristics such as reliability, simplicity, low maintenance and environmental friendliness, has increased their popularity even further.

The development of concentrators equipped with solar cells for increasing the efficiency of solar radiation collection is still evolving and not yet mature due the high cost involved in building efficient solar collectors and trackers.

U.S. Pat. No. 6,091,017 discloses a solar concentrator array with parallel rows of mirror assemblies mounted on a base plate having high thermal conductivity. Each mirror assembly comprises back-to-back mirror strips having reflecting front faces. Photovoltaic cells are placed on the plate between rows of mirror assemblies. The reflecting faces reflect incident light onto the photovoltaic cells to produce electric power. Preferably, the reflecting faces have a cylindrical parabolic configuration with a line of focus approximately along the interface between the photovoltaic cell and the edge of the opposite mirror strip adjacent to the cell.

### OBJECTS OF THE INVENTION

It an object of the current invention to provide an improved solar energy system, in particular with respect to at least one of: price, collection power, efficiency, reliability, simplicity and quantity of solar cells It is another object of the present invention to provide a solar energy apparatus that lowers the overall system cost by reducing the amount of solar cell material required for energy conversion without sacrificing performance.

It is another object of the present invention to provide a solar energy apparatus that relates to the problem of high cost of solar cell material by partially removing this material and replacing it with low cost mirrors preferably arranged in a retroreflector configuration.

### SUMMARY OF THE INVENTION

The present invention provides a solar energy apparatus with a tracker free solar concentrator and an arrangement of mirrors and solar cells oriented to each other in a manner similar to an optical retroreflector layout.

The invention is based on optical elements concentrating solar energy using simple mirror reflection for wide range of solar radiation incidence angles in order to build a tracker free apparatus.

In accordance with another preferred embodiment of present invention, the mirrors are selectively coated to reflect part of the sun's energy which best fits solar cell power generation efficiency, thus preventing excess heat from the solar cell.

In accordance with yet another preferred embodiment of the present invention, two solar cells are each optimized to a different portion of the solar radiation spectrum and preferably arranged orthogonal to each other. The mirrors are preferably orthogonal to the two solar cell elements, creating a configuration similar to an optical retroreflector.

According to still another preferred embodiment, the apparatus comprises three solar cells each optimized to a different portion of the solar spectrum and preferably arranged orthogonal to each other.

In accordance with another preferred embodiment of present invention, there is provided a set or system of units comprising a combination of mirrors and solar cells connected together to form a large area array.

Yet in another alternative embodiment the reflecting mirrors are partially transparent to visible light in order to create a substantially see-through solar generating element.

There is thus provided in accordance with a preferred embodiment of the present invention, a solar radiation concentrating apparatus based on mirrors and solar cells arranged in a mutually orthogonal arrangement. The apparatus includes one or more solar energy cells for converting radiation to another form of energy; two planar mirror elements, oriented to reflect solar radiation and to concentrate the radiation onto said solar energy cell. The two mirror elements being oriented substantially orthogonally to each other and to the solar cell. The two planar mirror elements and solar energy cell arranged in a configuration of three mutually perpendicular joined surfaces.

In accordance with another preferred embodiment of present invention the configuration, each consisting of a combination of mirrors and solar cells, are connected together to create a large area array.

In another alternative embodiment, reflected solar radiation is provided by a transparent refractive element shaped similarly to a retroreflector, while the solar cell is positioned and optically matched on one of its edges.

Preferably, the mirrors are selectively coated to reflect part of sun's radiation to improve solar cell power generation efficiency, thus preventing excess heat from the solar cell.

### BRIEF DESCRIPTION OF DRAWINGS

FIG. 1: Is a schematic layout of a photovoltaic cell mounted on one edge of a hollow retroreflector type mirror arrangement according to an embodiment of the present invention;

FIG. 2: Is a schematic description of an exemplary panel for generating solar energy in accordance with an embodiment of the present invention;

FIG. 3: Is a schematic illustration of a positioning of a solar cell concentrating unit with respect to the sun, and radiation distribution on its surface;

FIG. 4: Is a schematic layout of a photovoltaic cell mounted on one edge of a refractive solid retroreflector;

FIG. 5: Is a graphical illustration of an exemplary calculation of power generated by the apparatus of the invention collectively for several retroreflectors and photovoltaic cells arrangements; and

FIG. 6: Is a graphic depiction of a calculation describing the photovoltaic cell efficiency of the invention with respect to prior art flat panels.

### DETAILED DESCRIPTION OF EMBODIMENTS OF THE INVENTION

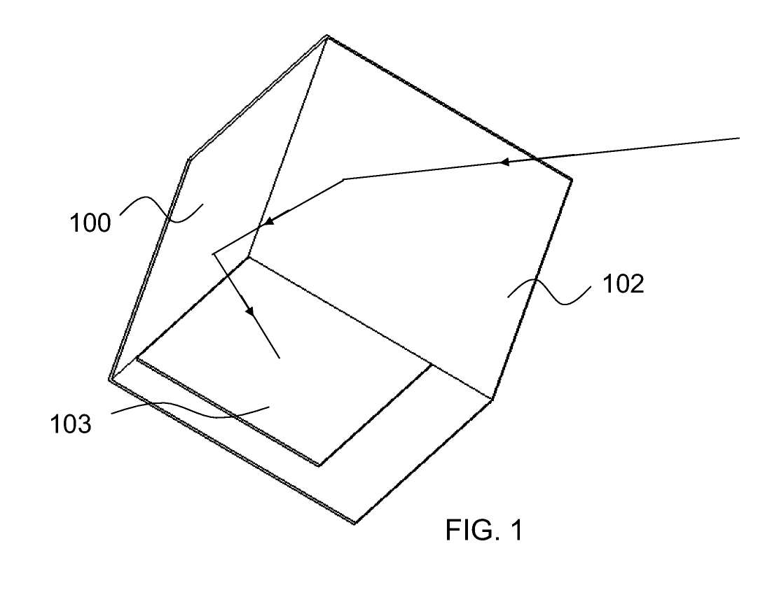

Reference is first made to FIG. 1 which is a schematic layout of a photovoltaic cell 103 mounted on one edge of a hollow retroreflector. The retroreflector is built from two reflecting surfaces 100 and 102 orthogonal to each other while the photovoltaic cell 103 is mounted on the third orthogonal surface. The photovoltaic cell 103 accepts both direct radiation incident on it and reflected radiation from one or two other reflecting surfaces 100 and 102 of the retroreflector. The photovoltaic cell 103 does not necessarily cover the whole area of the retroreflector edge, and its size and shape are optimized for maximum efficiency per photovoltaic cell unit area.

The reflecting surfaces 100 and 102 can be coated with a dichroic coating to reflect the part of the radiation spectrum relevant for generating solar power. Moreover, the reflecting surfaces 100 and 102 can be partially transparent to allow a see-through window.

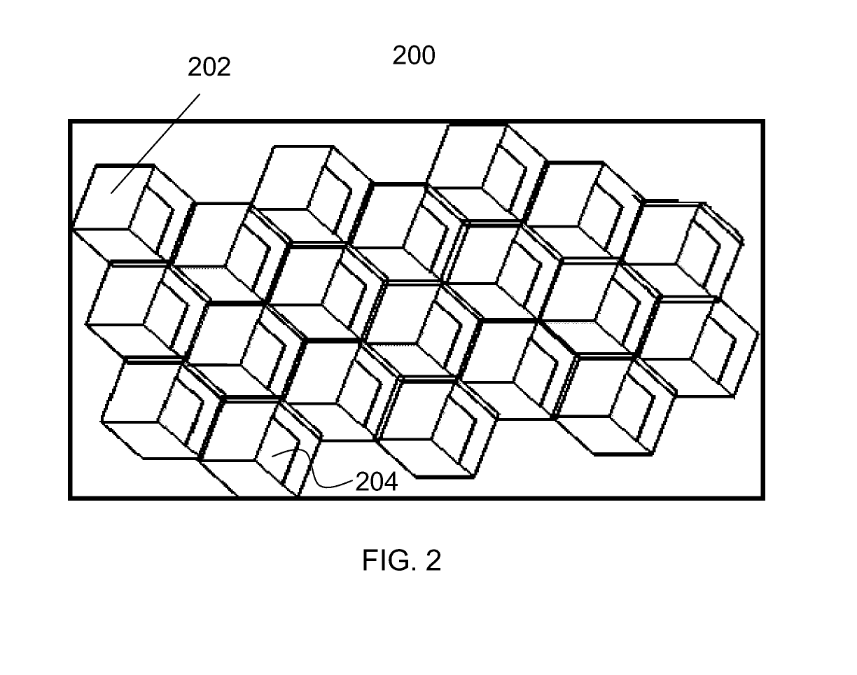

In FIG. 2 there is shown an exemplary panel 200 intended to generate solar energy comprising a two dimensional array of photovoltaic cells such as cell 202 mounted on retroreflectors 204.

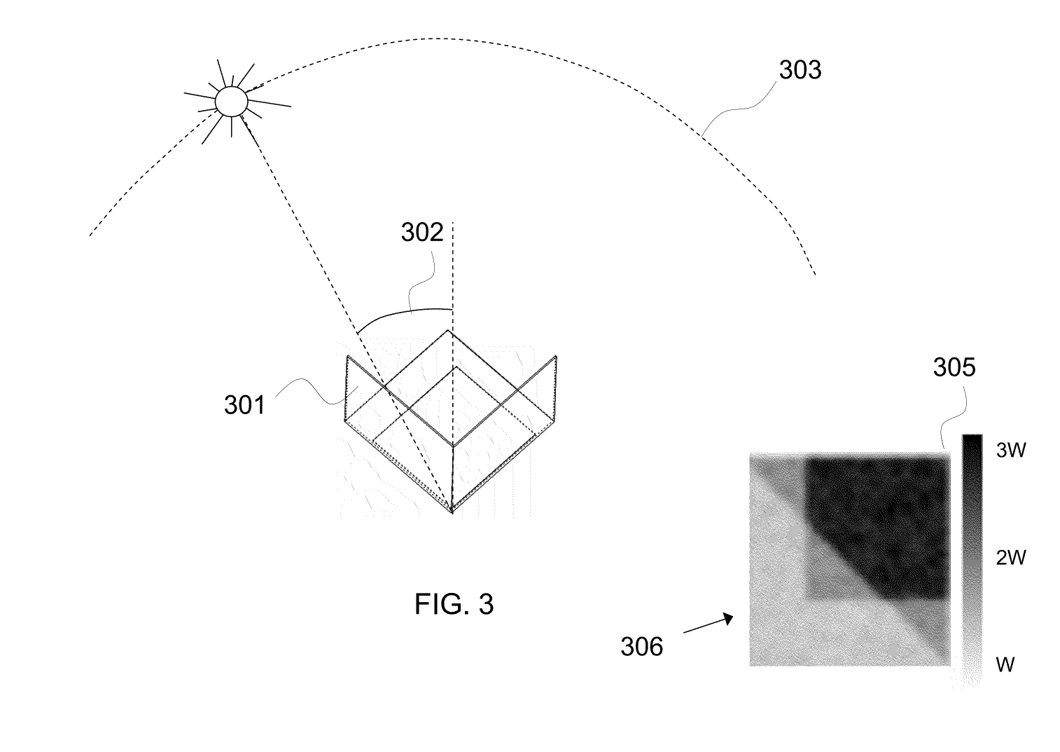

In FIG. 3 shows an exemplary positioning of the retroreflector 204 mounted on solar cell system 301, with respect to sun zenith angle 302 and path 304. Image 306 shows an example of a ray tracing simulation of the radiation energy distribution on the photovoltaic cell area. The gray scale shows several areas receiving radiation with intensity ranging from 1 W (direct sun radiation) to 3 W due to additional radiation reflected from two other retroreflector surfaces. A point 305 denotes the photovoltaic cell corner coinciding with the retroreflector vertex. It should be noted that the photovoltaic cell still gains reflections from other surfaces even beyond the regular acceptance angle for back reflection of the incident light beam.

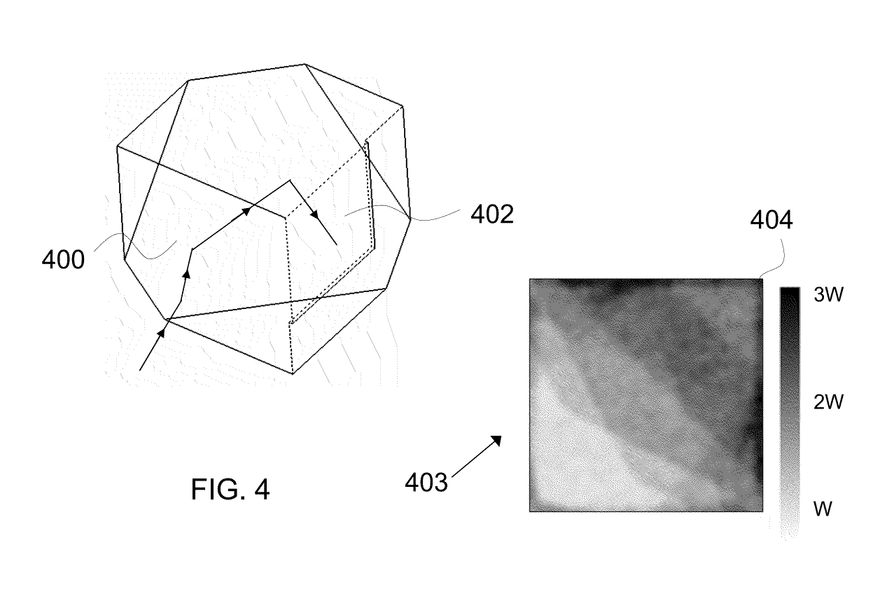

In FIG. 4 is a schematic layout of retroreflector 400 with photovoltaic cell 402 mounted on one edge. The retroreflector 400 is made of a refractive transparent material with three orthogonal edges reflecting the incident radiation by total internal reflection and/or additional reflecting coating. The photovoltaic cell 402 is mounted on the retroreflector surface by means of a refraction index matching material to optimize the radiation coupling. An image 403 shows an example of a ray tracing simulation of the radiation distribution on the photovoltaic cell area. A point 404 denotes the photovoltaic cell corner coinciding with the retroreflector vertex.

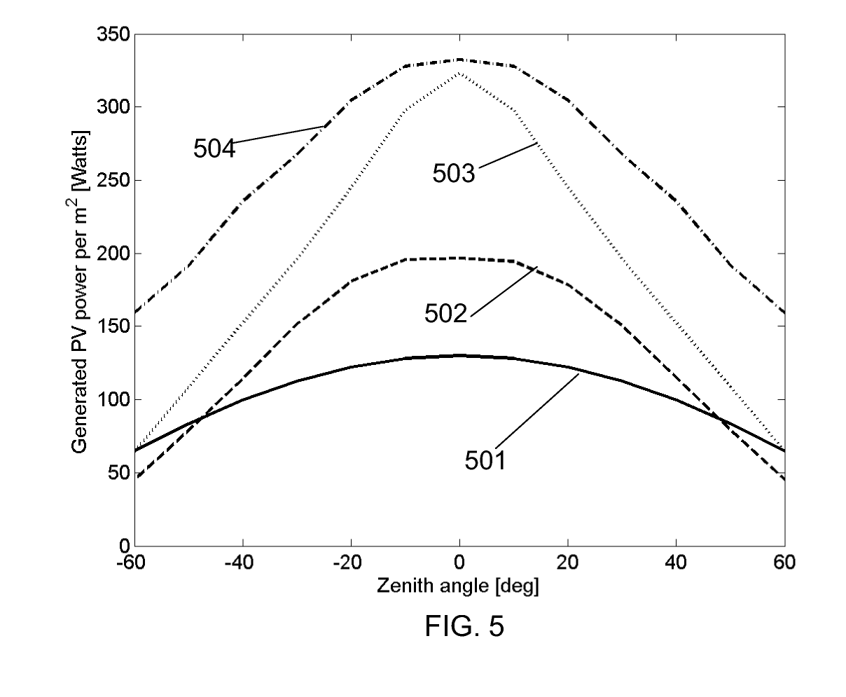

In FIG. 5 shows a graphical illustration of an exemplary calculation of the output power generated by the apparatus in accordance with the present invention. A photovoltaic cell with 13% efficiency and incident radiation of 1000 W/cm² were assumed. The plot shows the power generated by 1 m² of photovoltaic cells distributed on a prior art flat panel and different examples of retroreflectors versus the sun zenith angle. For comparison, graph line 501 shows the power generated by a prior art flat photovoltaic panel of 1 m² area. Graph line 502 shows the power generated by a photovoltaic panel of the present invention as shown in FIG. 2, comprising 100 hollow retroreflector units arranged on a 175 cm² panel, wherein the total cell area the photovoltaic cells is 100 cm², covering the entire retroreflector facet to its edge. Graph line 503 shows the power generated by the same 100 hollow retroreflector units but with a 50 cm² photovoltaic cell active area (i.e. covering half of the retroreflector facet area) adjacent the retroreflector vertex. Graph line 504 shows the power generated by 100 refractive retroreflectors, as illustrated in FIG. 4 (i.e. with a refractive transparent material) arranged on a 175 cm² panel, wherein the total cell area the photovoltaic cells is 50 cm², covering half the retroreflector facet adjacent the retroreflector vertex.

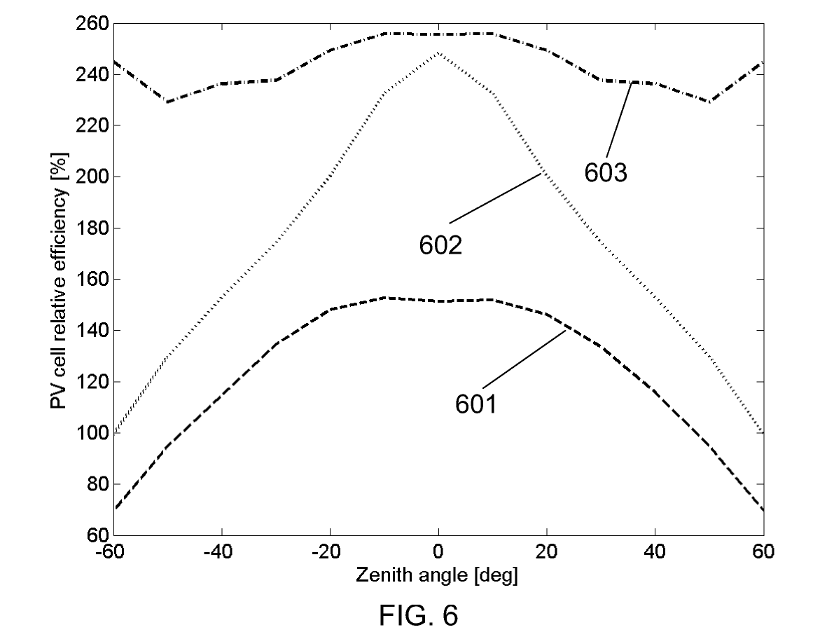

FIG. 6 shows the relative photovoltaic cell calculation efficiency based on the examples shown in FIG. 5. In FIG. 6 the graph shows the photovoltaic cell solar power generation efficiency based on the present invention with respect to prior art photovoltaic cells mounted on flat panels. The efficiency is calculated for an equal area of 1 m² photovoltaic cells mounted on retroreflectors, relative to photovoltaic cells mounted on a prior art flat panel. Graph line 601 represents the efficiency of 100 hollow retroreflector units with a 100 cm² photovoltaic cell. Graph line 602 represents the efficiency of 200 hollow retroreflector units with a 50 cm² photovoltaic cell mounted close to the retroreflector's vertex. Graph line 603 represents the efficiency of a 200 refractive retroreflectors with a 50 cm² photovoltaic cell mounted close to the vertex. It should be noticed that the refractive retroreflectors array has almost constant efficiency for solar zenith angles from −60° to +60°. This shows that the present invention enables up to 250% more solar energy to be generated by standard solar cells.

1. A solar power generating device comprising:
a solar energy cell capable of converting the suns energy into a form of useful energy.
mirror elements, oriented to reflect solar energy onto said solar cell, preferably two orthogonally oriented to each other and to said solar cell, creating a configuration similar to an optical retro reflector.

2. A device according to claim 1, wherein said reflection is provided by a transparent refractive element shaped similarly to retroreflector, while said solar cell is positioned and optically matched on one of its edges.

3. A device according to claims 1 and 2, where said mirrors are selectively coated to reflect part of sun's energy which best fits solar cell power generation efficiency, thus preventing excess heat from said solar cell.

4. The device as in claim 1 further comprising of:
two solar cells each optimized to a different part of the solar spectrum preferably orthogonal to each other.
a mirror orthogonal to said two solar cell elements creating a configuration similar to an optical retro-reflector.

5. The device according to claim 4 further comprising of three solar cells each optimize to a different part of the solar spectrum preferably orthogonal to each other.

6. The device according to claims 1-5, when the said of optical elements each consisting of combination of mirrors and solar cells, are connected together to create a large area array.

7. A device according to claims 1-6, when the said reflecting mirrors are partially transparent for a visible light in order to create a see-through solar generating element.

8. A solar power generating method comprising:
a solar cell capable to convert the suns energy into electrical or some other form of useful energy.
mirrors oriented to reflect solar energy onto said solar cell, preferably two orthogonally oriented to each other and to said solar cell, creating a configuration similar to an optical retro reflector.

9. A method according to claim 8, wherein said solar radiation reflection is provided by a transparent refractive element shaped similarly to retroreflector, and wherein said solar cell is positioned and optically matched on one of its edges.

10. A method according to claims 8 and 9, where the said mirrors are selectively coated to reflect part of sun's energy which best fits solar cell power generation efficiency, thus preventing excess heat from said solar cell.

11. The method further comprising of:
Two solar cells each optimized to a different part of the solar spectrum preferably orthogonal to each other.
a mirror set orthogonal to said two solar cell elements, creating a configuration similar to an optical retro reflector.

12. The method according to claim 11 further comprising of three solar cells each optimize to a different part of the solar spectrum preferably orthogonal to each other.

13. The method according to claims 8-12, when the said of optical elements each consisting of combination of mirrors and solar cells, are connected together to create a large area array.

14. A method according to claims 8-13, when the said reflecting mirrors are partially transparent for a visible light in order to create a see-through solar generating element.
